(19) United States
(12) Patent Application Publication
(10) Pub. No.: US 2009/0242386 A1
(43) Pub. Date: Oct. 1, 2009

(54) System and Method of Fabricating Pores in Polymer Membranes

(76) Inventors: Renato Amaral Minamisawa, Aachen (DE); Robert Lee Zimmerman, Huntsville, AL (US); Daryush Ila, Huntsville, AL (US)

Correspondence Address: LANIER FORD SHAVER & PAYNE P.C., P O BOX 2087, HUNTSVILLE, AL, 35804-2087, US

(21) Appl. No.: 12/412,874

(22) Filed: Mar. 27, 2009

Related U.S. Application Data
(60) Provisional application No. 61/040,050, filed on Mar. 27, 2008.

(51) Int. Cl. C23C 14/32

(52) U.S. Cl. 204/192.11; 204/298.32

(57) ABSTRACT

A system of the present disclosure has a particle source that generates an ion beam and a vacuum chamber that houses a polymer film. The particle source bombards the polymer film with the ion beam. The system further has a controller that controls the particle source based upon an amount of the gas detected within the vacuum chamber.

### REFERENCE TO RELATED APPLICATIONS

This application claims priority to U.S. Provisional Patent Application Ser. No. 61/040,050, entitled “System and Method for Micro and Nano Porous Membranes,” filed on Mar. 27, 2008, which is fully incorporated herein by reference.

### STATEMENT REGARDING FEDERALLY SPONSORED RESEARCH OR DEVELOPMENT

This invention was made with Government support under Grant No. 392153004966122 awarded by the National Science Foundation. The Government has certain rights in this invention.

### BACKGROUND

Micro porous and nano porous membranes are affordable and reliable devices for applications involving filtration processes. Such membranes may be used in water treatment processes for sustainable growth and for better effluent treatment in chemicals, pharmaceuticals, food, and other industries. In addition, such membranes may be used in miniaturized biomedical systems, such as dialysis or respiration.

Several materials have been used to manufacture membranes, such as silicon, ceramics, glass, and metals. In addition, polymers have been used in the industry where chemical stability and low unit cost are desired.

In this regard, some of the most commercialized filtration membranes are fabricated from polytetrafluoroethylene (Teflon PTFE) material, whose properties include being chemically inert and resistant to relatively elevated temperatures. In addition, fluoropolymer materials such as perfluoroalkoxyethylene (Teflon PFA) and fluorinated ethylene propylene (Teflon FEP) present similar inert properties, leading to equal resistance to chemical and biological degradation.

There exist in the industry several methods of manufacture of micro porous and nano porous membranes. Such methods include chemical processing, ion track etching, molding, in-print techniques, laser ablation, reactive plasma etching and focused ion beam techniques (FIB). Note that in reactive ion etching, there is a chemical reaction that occurs between ions and the material being irradiated.

### SUMMARY

A system for micro porous and nano porous manufacture in accordance with an embodiment of the present disclosure comprises a particle source that generates an ion beam and a vacuum chamber that houses a polymer film. The particle source bombards the polymer film with the ion beam. The system further has a controller that controls the particle source based upon an amount of the gas detected within the vacuum chamber.

A method in accordance with an embodiment of the present disclosure comprises generating an ion beam, bombarding a polymer film in a vacuum chamber with the generated ion beam, and detecting data indicative of an amount of gas within the vacuum chamber. The method further comprises controlling delivery of the ion beam to the polymer film based upon the detected data.

### BRIEF DESCRIPTION OF THE DRAWINGS

The present disclosure is described with reference to the accompanying drawings. In the drawings, like reference numbers indicate identical or functionally similar elements. Additionally, the left-most digit(s) of a reference number identifies the drawing in which the reference number first appears.

FIG. 1 is a block diagram of an exemplary system in accordance with an embodiment of the present disclosure.

FIG. 2 is a block diagram of the system of FIG. 1 showing the progressive formation of a pore in a polymer film.

FIG. 3 is a detailed depiction of the system of FIG. 1.

FIG. 4 is a perspective view of a polymer film and a stencil template of the system of FIG. 1.

FIG. 5 is a graph depicting phases of pore formation by the system of FIG. 1.

FIG. 6 is a block diagram of a computing device of the system depicted in FIG. 3.

FIG. 7 is a cross-sectional view of an exemplary instrument in accordance with an embodiment of the present disclosure.

FIG. 8 is an exploded cross-sectional view of Detail A of FIG. 7.

FIG. 9 is a flowchart depicting architecture and functionality of the system depicted in FIG. 1.

### DETAILED DESCRIPTION

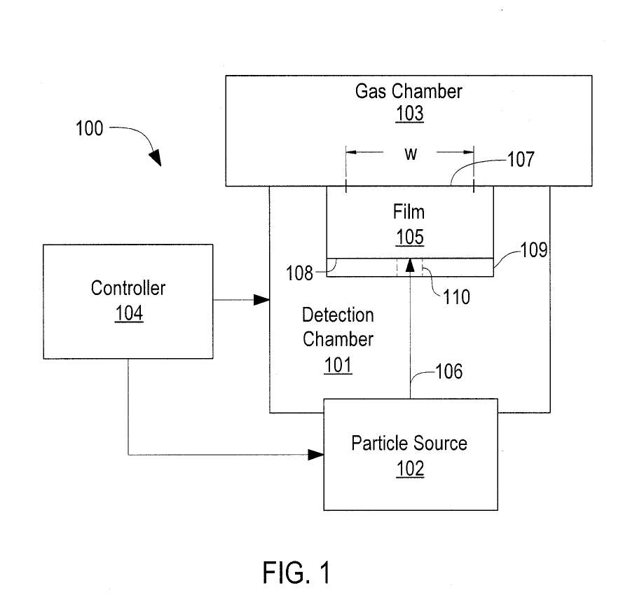

The various embodiments of the present disclosure and their advantages are best understood by referring to FIGS. 1-9. The elements of the drawings are not necessarily to scale, emphasis instead being placed upon clearly illustrating the principles of the disclosure. Throughout the drawings, like numerals are used for like and corresponding parts of the various drawings.

FIG. 1 is a block diagram of an ion beam sculpting system 100 in accordance with an embodiment of the present disclosure. The ion beam sculpting system 100 comprises a detection chamber 101, a gas chamber 103, a particle source 102, and a controller 104.

The detection chamber 101 houses a polymer film 105 that is physically coupled to a stencil template 109. The polymer film 105 may be made of polytetrafluoroethylene (Teflon PFE), perfluoroalkoxyethylene (Teflon PFA) and fluorinated ethylene propylene (Teflon FEP), for example. In other embodiments of the present disclosure, the polymer film 105 may be made of other types of materials known in the art or future-developed.

The stencil template 109 comprises an opening 110. In one embodiment, the stencil template 109 is an arrangement of geometrical patterns, for example circles or squares. In addition, the stencil template 109 can be made of any type of metal known in the art, including gold.

The polymer film 105 separates the gas chamber 103 from the detection chamber 103. In this regard, prior to operation of the ion beam sculpting system 100, gas (not shown) contained in the gas chamber 103 is prohibited from traveling from the gas chamber 103 to the detection chamber 101 by the polymer film 105.

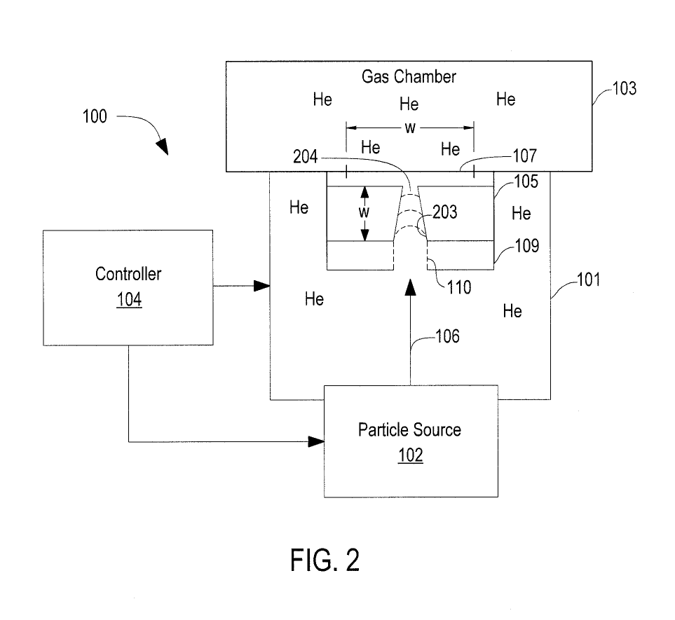

In one embodiment, the gas chamber 103 has an opening 107. In such an embodiment, the polymer film 105 is attached to the gas chamber 103 thereby covering the opening 107. Further, the gas chamber 103 is filled with a gas (not shown). In one embodiment, the gas within the gas chamber 103 is an inert gas, such as, for example Helium (He). The gas chamber 103 is described further with reference to FIG. 2.

The particle source 102 generates an ion beam 106 that enters the detection chamber 101 and bombards a surface 108 of the polymer film 105 with ions (not shown) through the stencil template 109. Notably, only that portion of the polymer film 105 that is aligned with the opening 110 in the stencil template 109 is bombarded by ions in the ion beam 106.

In one embodiment of the present disclosure, the ion beam 106 is a scanned ion beam and the polymer film 105 is made of a fluoropolymer or Teflon material. A “Teflon material” is one from a group comprising, for example, polytetrafluoroethylene (Teflon PTFE), perfluoroalkoxyethylene (Teflon PFA) and fluorinated ethylene propylene (Teflon FEP).

The ions in the ion beam 106 cause both ablation and sputtering on the surface 108 of the polymer film 105. The term “ablation” refers to the breaking of chemical bonds in the polymer film 105 due to the delivery of energy to the polymer film 105, but not limited to the surface region. The term “sputtering” refers to the mechanical removing of surface material due to ion collisions. At the locations on the polymer film 105 at which the ion beam ablates the chemical bonds in the polymer film 105 and sputters the atoms and/or molecules on the polymer film 105 surface 108, wells or indentations (not shown) begin to form in the polymer film 105, which is described further with reference to FIG. 2.

Note that the ion beam 106 produced by the particle source 102 can be comprised of any type of ions known in the art, including, but not limited to Gold (Au) ions. In one embodiment, the particle source 102 produces a 5 mega electron volt (MeV) Gold (Au) ion beam, which is comprised of Au⁺³ ions.

With reference to FIG. 2, after continued bombardment by the ions in the ion beam 106, a well 203 is formed in the polymer film 105. As the ions in the ion beam 106 continue to bombard the polymer film 105, the deeper the well 203 becomes. After a particular duration, the ion beam 106 creates a pore 204 in the opposite side of the polymer film 105.

Note that the size of the well 203 and the pore 204 on the opposing side is related to the fluence of the ion beam 106. “Fluence” is a term that refers to the number of particles, for example ions, that accumulate on a surface, i.e., ions/centimeter² (ions/cm²). As an example, the fluence of the Au⁺³ may be 5×10⁻¹³ ions/cm².

Further, the current produced by the ion beam 106 is measured by the number of incident ions (charge) per second, i.e., charge/second. As an example, an ion can have a charge higher or lower than + or −1.

Note that the higher the current, the higher the rate of incident ions. Further note that the higher the rate of incident ions, the faster wells and pores can be formed on the polymer film 105. In addition, the energy of an ion is directly proportional to the applied voltage in the charge, and the power is the product of the current multiplied by the voltage. Since the power represents the energy delivered, it is proportional to the ablation of the material.

Therefore, the time that it takes for the well 203 to be formed and the pore 204 to be created on the opposite side of the opening 203 is directly related to the current measurement. In this regard, the higher the current of the ion beam 106, the faster the wells 203 and the pores 204 are created. This is described further herein.

In FIG. 2, the gas chamber 103 is shown as filled with Helium (He) for illustrative purposes. Once the pore 204 is formed in the polymer film 105, the helium gas flows from the gas chamber 103 to the detection chamber 101.

Note that in one embodiment, the gas chamber 103 is maintained at atmospheric pressure, which is 1013 millibars (mbar). Further, the detection chamber 101 is maintained as a vacuum. In one embodiment, the detection chamber 101 is kept at approximately 10⁻⁶ torr vacuum pressure and ambient temperature using a vacuum pump (not shown). Thus, when the pore 204 is formed in the polymer film 105, the helium gas flows from the higher pressure, the atmospheric pressure of the gas chamber 103, to the lower pressure of the vacuum formed in the detection chamber 101.

The controller 104 is in fluid communication with the detection chamber 101. In addition, the controller 104 is communicatively coupled to the particle source 102. During operation, the controller 104 monitors the helium gas flow within the detection chamber 101. Once the controller 104 determines that there has been an increase in the helium gas flow into the detection chamber 101, the controller 104 deactivates the particle source 102. In this regard, the controller discontinues the beam 106 once the pore 204 in the polymer film 105 has reached a desired diameter. This is described further herein.

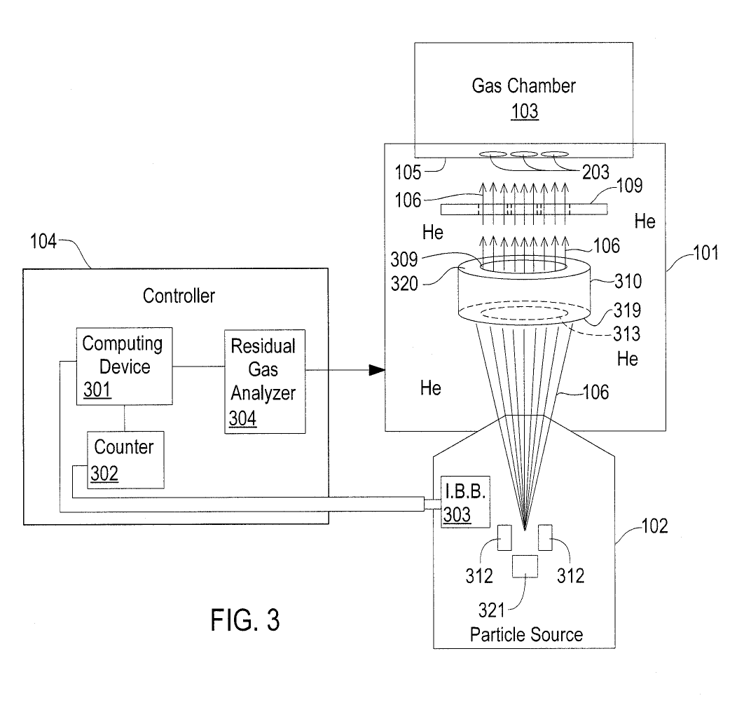

FIG. 3 depicts an exemplary embodiment of the system 100 as depicted in FIG. 1. In such an embodiment, the detection chamber 101 houses a Faraday cup 310, the stencil template 109, and the polymer film 105.

The Faraday cup 310 is a metal housing that can be used to determine the fluence of the ions from the ion beam 106 produced by the particle source 102. In this regard, when ions from the ion beam 106 impact an inner wall 315 of the Faraday cup 210, the Faraday cup 310 produces a measureable current that can be used to calculate the fluence of the ion beam 106.

The Faraday cup 310 has an entrance opening 313 in an entrance side 319 and an exit opening 309 in an exit side 320. The ion beam 106 enters the Faraday cup 310 through the opening 313. The Faraday cup 310 collimates the ion beam 106 and the collimated ion beam 106 exits the Faraday cup 310 through the opening 309.

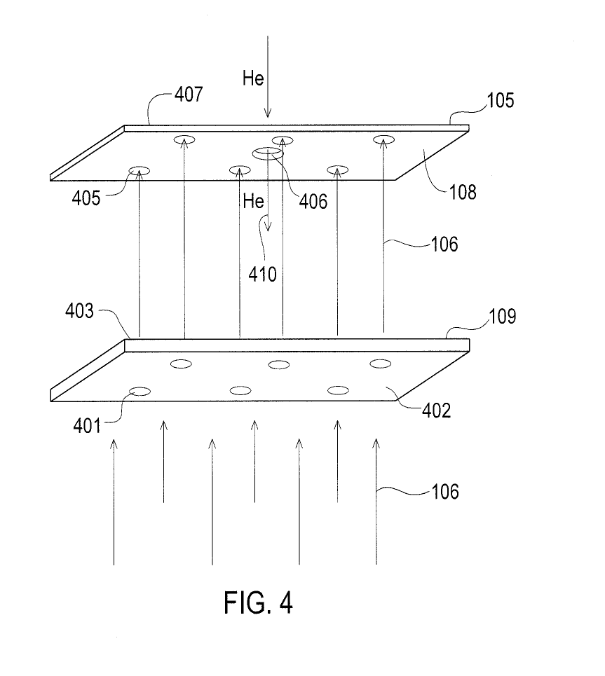

As described herein, the stencil plate 109 comprises an arrangement of geometrical patterns, for example circles or squares, through which a portion of the beam 106 can travel and bombard the polymer film 105. The stencil template 109 only exposes those portions of the polymer film 105 corresponding to the geometrical patterns, which is described further with reference to FIG. 4.

The particle source 102 comprises an ion accelerator 321 and one or more deflector plates 312. The ion accelerator 321 generates a beam of ions having a small diameter (not shown). The deflector plates 312 scan the ion beam generated by the ion accelerator 321 to generate the scanned ion beam 106. As indicated herein, the ion beam 106 may be, for example comprised of gold ions (Au⁺³).

Note that the accelerator/deflector plate arrangement shown in FIG. 3 is for exemplary purposes. Other arrangements may be used in other embodiments of the present disclosure. As an example, a vertically positioned particle source (not shown) may be positioned to direct a scanned ion beam at a Teflon film (not shown) that is pulled from a film cassette (not shown).

During operation, the ion beam 106 enters the opening 313 in the Faraday cup 310. The ion beam 106 travels through the Faraday cup 310 and exits the Faraday cup 310 through the opening 309. The ion beam 106 strikes the stencil template 109, which allows only a portion of the beam 106 through to strike the polymer film 105. In this regard, only a portion of the beam 106 is allowed through to strike the polymer film 105 because the stencil template 109 has openings (not shown) that only allow a portion of the ion beam 106 through the stencil template 109 to the polymer film 105.

As the ions in the ion beam 106 irradiate the polymer film 105, through ablation and sputtering the ion beam 106 drill portions of the polymer film 105 that are directly bombarded by the ion beam 106. After continued bombardment, the wells 203 (FIG. 2) and corresponding pores 204 (FIG. 2) form. Thus, inert gas contained in the gas chamber 103 flows from the gas chamber 103 to the detection chamber 101.

In addition, the controller 104 of the exemplary system 100 depicted in FIG. 3 comprises a residual gas analyzer (RGA) 304, a computing device 301, and a counter 302, and an ion beam blocker 303.

The RGA 304 monitors the diffusion of the inert gas, e.g., He, through the detection chamber 101. As described herein, the detection chamber 101 is kept at vacuum, i.e., at absolute pressure, and the gas chamber 103 is kept at atmospheric pressure. Thus, the inert gas diffuses through the detection chamber 101 from the gas chamber 103.

When helium is employed as the inert gas in the gas chamber 103, there is some initial diffusion without the formation of pores 204 (FIG. 2). Such initial diffusion through the polymer film 105 is due to helium's light atomic mass.

In so monitoring, the RGA 304 obtains mass and partial pressure values of the inert gas within the detection chamber 101. In one embodiment, the RGA monitors the diffusion of the inert gas during bombardment and after creation of the pores 204 (FIG. 2). Note that the polymer film 105 may initially have a tracer opening, described further with reference to FIG. 4, that allows a tracer amount of helium to enter the detection chamber 101 prior to creation of the pores 204 (FIG. 2).

When bombardment is accomplished and pores 204 are formed in the polymer film 105, the RGA detects an increase in the helium present in the detection chamber 101, because the amount of helium that escapes the gas chamber 103 into the detection chamber 101 increases. This increase in the presence of the inert gas in the detection chamber 101 is a result of an increase in the flow of the inert gas through the formed pores 204. Notably, the RGA 304 detects the mass and partial pressures of the elements in the detection chamber 101.

The counter 302 is a coulter counter that is electrically connected to the Faraday cup 310. The counter 302 receives an electrical signal from the Faraday cup 310. The counter 310 calculates, based upon the current of the electrical signal, the fluence of the ion beam 106 traveling from the opening 313 to the exit 309.

The computing device 301 is communicatively connected to the RGA 304 and the counter 302. During operation, the computing device 301 analyzes the information obtained from the RGA 304 and/or the counter 302 in order to control the ion beam blocker 303.

The ion beam blocker 303 moves into the ion beam 106 prohibiting the ion beam 106 from entering the Faraday cup 310. In another embodiment, the Faraday cup 310 is movable, and the computing device 301 moves the Faraday cup 310 in order to block the ion beam 106 from the polymer film 105.

In one embodiment, the computing device 301 monitors the partial pressure related to the mass of the inert gas diffusing through the detection chamber 101. When there is an increase in the partial pressure related to the mass of the inert gas, the computing device 301 moves the ion beam blocker 303 into the path of the ion beam 106, thus completing the formation of the pores 204 in the polymer film 105.

Furthermore, a fluence for five minutes, for example, produces a pore 204 having a diameter of approximately 50 nanometers (nm). Whereas a particular fluence for 10 minutes produces a pore 204 having a diameter of approximately 100 nm.

Thus, in another embodiment, the computing device 301 monitors the fluence as calculated by the counter 302. In such an embodiment, the computing device 301 also determines that a pore 204 has been created by a measured increase in partial pressure. Based upon previously measured experimental data, the computing device 301 deactivates the particle source 102 by moving the ion beam blocker 303, a particular duration of time has passed for the measured fluence.

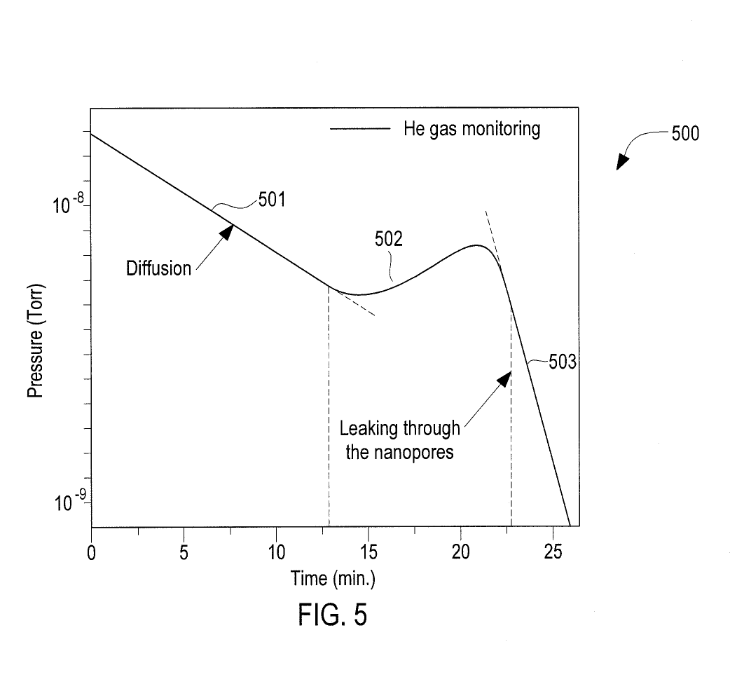

FIG. 4 depicts exemplary embodiments of the stencil template 109 and the polymer film 105. In such an embodiment, the stencil template 109 comprises an array of circular openings 401. As indicated herein, other geometric shapes, for example squares, can be used in other embodiments of the present disclosure. The stencil template 109 is aligned with the polymer film 105. Note that in one embodiment, the polymer film 105 is coupled to the opening 107 (FIGS. 1 & 2) of the gas chamber 103 (FIG. 1-3). In addition, the stencil template 109 may be held in physical contact along the surface 108 of the polymer film 105 with a sample holder, which is described further with reference to FIG. 5.

During operation, the ion beam 106 strikes a face 402 of the stencil template 109. Portions of the ion beam 106 strike a face 402 of the stencil template 109 and portions of the ion beam 106 continue through the openings 401 in the stencil template 109. In this regard, the openings 401 allow the portion of the ion beam 106 that enter the openings 401 to exit from an opposite face 403.

Those portions of the ion beam 106 that escape the face 403 of the stencil template 109 irradiate the surface 108 of the polymer film 105 and ablate and sputter the polymer film 105. The ablation and sputtering that occurs forms wells 203 (FIG. 2) and eventually pores 204 (FIG. 2) in the surface 108 of the polymer film 105.

Note that the fluence at which bombardment is effectuated can vary. For example, the polymer film 105 may be bombarded at fluences of 5×10¹², 5×10³ ions/cm², 2×10¹³, or 3×10¹³ ions/centimeter² (ions/cm²). As discussed herein, the fluence at which the ions bombard the surface 108 of the polymer film 105 relate to the size of the openings 203 (FIG. 2) and corresponding pores 204 (FIG. 2) that are formed in the polymer film 105.

In one embodiment, the stencil template 109 is comprised of metal, for example copper, gold, or the like. However, the stencil template 109 can be comprised of any type of material known in the art or future-developed. Further, in one embodiment, the stencil template 109 is 25 micro meters squared (μm²). However, other sizes of stencil templates 109 may be used in other embodiments.

After continued bombardment of the polymer film 105 by the ion beam 106, the pores 204 (FIG. 2) form on an opposing surface 407 of the polymer film 105. Note that the surface 407 is the surface originally exposed to the gas chamber 103. As the pores 204 form, the helium gas flows from the gas chamber 103 through the pores 204 to the detection chamber 101 (FIGS. 1-3). As will be described further herein, as the pores 204 increase in diameter, the amount of helium in the detection chamber 101 increases as well. Thus, there is a direct relationship between the diameter of the pore 204 and the amount of helium within the detection chamber 101.

In one embodiment, the polymer film 105 comprises a trace opening 406 through which helium initially flows, in addition to that which may flow from the gas chamber 103 to the detection chamber 101 due to the porous nature of the polymer film 105 and the size of the inert gas atoms. In such an embodiment, before pores 204 form in the opposing surface 407, there is a trace amount of helium in the detection chamber 101. This trace amount of helium initially flows through the trace opening 406, as indicated by reference arrow 410. The rate of helium leaking through the pores can be measured and monitored in order to determine the initial pore formation time, i.e., when the pores 204 form in the opposing surface 407. From the rate of helium leaking through the pores, it is also possible to determine the final pores size.

As described herein, the detection chamber 101 houses the polymer film 105. As further described herein, in one embodiment the polymer film 105 covers the opening 107 in the gas chamber 103. Thus, any gas contained in the gas chamber 103 does not flow from the gas chamber 103 to the detection chamber 101. Also as described herein, the gas chamber 103 is maintained at atmospheric pressure, whereas the detection chamber 101 is maintained as a vacuum.

The trace opening 406 is created in the polymer film 105. The trace opening 406 allows a trace amount of helium to escape the gas chamber 103 as indicated herein. This trace amount of helium can be detected and monitored by the residual gas analyzer 304 described with reference to FIG. 3. Thus, when this trace amount of helium increases in the detection chamber 101 when a pore 204 is formed, the computing device 301 can deactivate the particle source 102.

FIG. 5 is a graph 500 depicting diffusion of helium gas in the detection chamber 101 (FIGS. 1-3) during the process of pore formation. During the initial phase from time=zero to time=12.5 minutes, the helium gas slowly diffuses through the polymer film 105 (FIG. 1-3) (or the trace opening 406 (FIG. 4) into the detection chamber 101 and out the detection chamber 101 via the vacuum pump (not shown). Such diffusion is indicated in the graph as line 501 having a constant and negative slope.

Note that from time=zero to time=12.5 minutes, there is a decrease in pressure. The decrease in pressure results from diffusion of the helium to the vacuum pump (not shown) as the helium moves from the gas chamber 103, through the detection chamber 101, and out of the chamber 101 toward the pump.

At 12.5 minutes an ion beam 106 (FIG. 2) forms a pore 204 (FIG. 2) in the polymer film 105. When the pore 204 is formed there is an increase in the amount of helium that escapes from the gas chamber 103 into the detection chamber 101. The increase is indicated by the positive slope of the curved line 502 showing an increase in partial pressure from 12.5 minutes to approximately 22.5 minutes. The increase in partial pressure indicates an increase in mass of the helium within the detection chamber 101.

During operation, the computing device 301 (FIG. 3) monitors the partial pressure values and/or mass of a selected gas obtained from the RGA 304 measurement (FIG. 3). If the computing device 301 determines that the partial pressure measured by the RGA 304 has increased, i.e., there has been an increase in helium partial pressure within the detection chamber 101, the computing device 301 activates the ion beam blocker 303 (FIG. 3) so as to interfere with the ion beam 106. Therefore, the polymer film 105 is no longer being bombarded with ions, and the pore 204 ceases to increase in diameter.

As the amount of helium in the gas chamber 103 exhausts through diffusion by the pump, the amount of helium in the detection chamber 101 decreases. This decrease in the detection chamber 101 of the helium is detected by the RGA 304 (FIG. 3), and is indicated in graph 500 by the negatively sloping line 503.

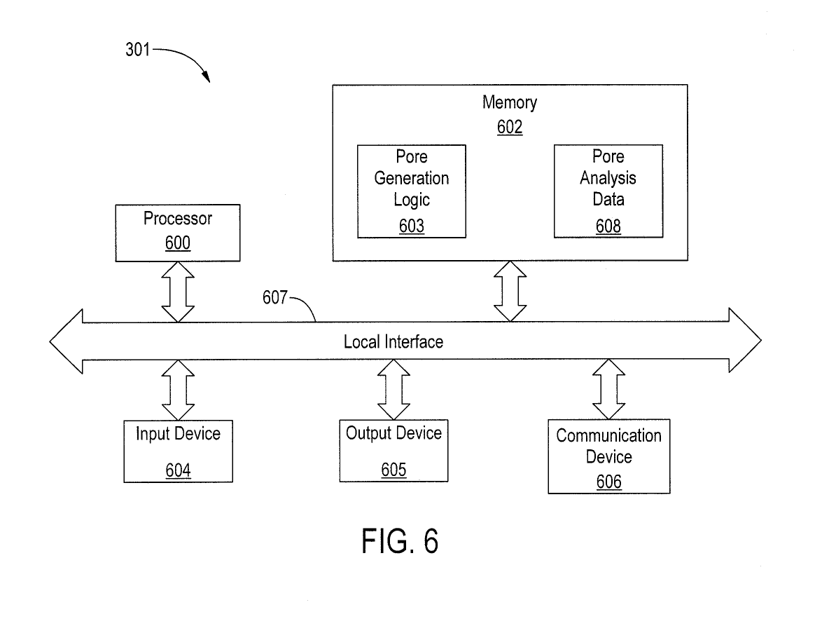

FIG. 6 is a block diagram depicting an exemplary computing device 301 of the present disclosure. The exemplary computing device 301 generally comprises a processor 600, an output device 605, an input device 604, and a communication device 606. Each of these components communicates over a local interface 607, which can include one or more buses.

Computing device 301 further comprises pore generation logic 603 and pore analysis data 608. The pore generation logic 603 can be software, hardware, or a combination thereof. In the exemplary computing device 301 shown in FIG. 6, pore generation logic 603 is shown as software stored in memory 602. Further, pore analysis data 608 is shown as stored in memory 602.

Memory 602 may be of any type of memory known in the art, including, but not limited to random access memory (RAM), read-only memory (ROM), flash memory, and the like. In addition, memory 602 may further comprise a database (not shown) for indexing, storing, and retrieving the pore analysis data 608.

As noted hereinabove, pore generation logic 603 is shown in FIG. 6 as software stored in memory 602. When stored in memory 602, the pore generation logic 603 can be stored and transported on any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

Processor 600 may be a digital processor or other type of circuitry configured to run the pore generation logic 603 by processing and executing the instructions of the pore generation logic 603. The processor 600 communicates with and drives the other elements within the computing device 301 via the local interface 607.

The communication device 606 may be, for example, any type of port and/or driver for connecting to peripheral devices (not shown). As an example, the communication device 606 may be a personal computer card (PC card) that is designed to specifically interface with the RGA 304 (FIG. 3) and/or the ion beam blocker 303 (FIG. 3). Further, the communication device 606 may also be a standard universal serial bus (USB) port that can connect to one or more peripheral devices.

The output device 605 visually communicates data and/or information to a user (not shown) of the computing device 201. In this regard, the display device 605 may be, for example, a liquid crystal display (LCD) screen.

The input device 604 enables the user to enter information and/or data into the computing device 301. In one embodiment, the input device 604 is a keyboard, and the user uses the keyboard facilitate operation of the pore generation logic 603, which is described further herein.

Pore analysis data 608 refers to data indicative of information related to, for example, the partial pressure and mass content of the detection chamber 101 (FIGS. 1-3). In addition, the pore analysis data 608 may comprise information and/or data related to the fluence of the ion beam 106 (FIGS. 1-3) that is propagating through the detection chamber 101.

Note that the pore analysis data 608 may comprise data entered by the user related to the pore generation logic 603. In this regard, through experimentation, the user may determine that a particular fluence for a particular duration generates a specific pore size in the polymer film 105. This data may be stored manually in the pore analysis data 608 for use by the pore generation logic 603.

During operation, the pore generation logic 603 receives pore analysis data 608 from the RGA 304 (FIG. 3) via the communication device 606. Such pore analysis data 608 is indicative of the presence and quantity of gas within the detection chamber 101 (FIG. 3).

With reference to FIG. 5, the pore generation logic 603 initially receives pore analysis data 608 indicate a decrease in partial pressure over time as indicated by graph line 501. When a pore is formed in the polymer film 105, the pore generation logic 603 receives pore analysis data 608 indicative of an increase in the partial pressure, over time, of the detection chamber 101, as indicated by the sinusoidal line 502 (FIG. 5).

In one embodiment, after a particular duration, the pore generation logic 602 activates the ion beam blocker 303 (FIG. 3). The duration after which the pore generation logic 602 activates the ion beam blocker 303 may be based upon predetermined data. As an example, through experimentation, it may be determined that a pore size of 50 nm may be accomplished if the ion beam 106 (FIG. 3) exhibits a fluence of 1×10⁻¹³ over a period of 10 minutes. In such an embodiment, the fluence of the ion beam 106 is obtained from the counter 302 (FIG. 3) via the communication device 606. Therefore, after 10 minutes, the pore generation logic 603 activates the ion beam blocker 303.

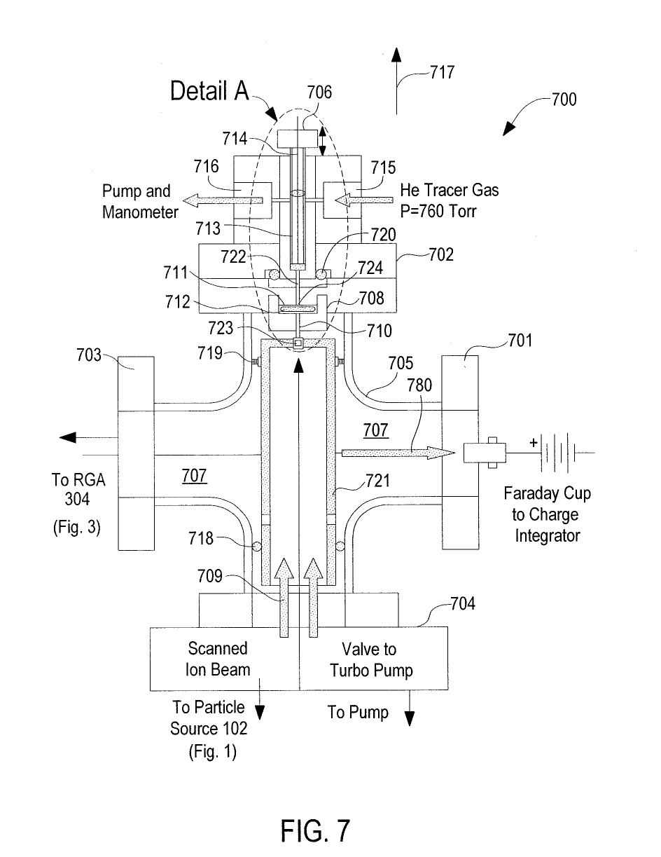

FIG. 7 is a cross-sectional view of an instrument 700 in accordance with another embodiment of the present disclosure. The instrument 700 comprises four flanges 701, 702, 703, and 704. In addition, the instrument 700 comprises a housing 705.

Flange 701 connects to the counter 302 (FIG. 3), and flange 702 connects to a gas pump 706. Flange 703 couples to the RGA 304 (FIG. 3), and flange 704 couples to the particle source 102 (FIG. 2). In addition, flange 704 comprises a valve (not shown), which couples to the vacuum pump (not shown), as described herein.

The housing 705 houses the Faraday cup 721, which receives an ion beam 709 from the particle source 102. In addition, the valve, when actuated, creates a vacuum within the space 707 created by the housing 705. Notably, one or more O-rings 718 are situated within the housing 705 and about the Faraday cup 721 in order to create the vacuum in the space 707 within the housing 705. Further note that one or more Teflon screws 719 couple the Faraday cup 721 to the housing 705 while still allowing the vacuum pump to create the vacuum with the space 707. Furthermore, an O-ring 720 may be used where the flange 702 houses the gas pump 706.

The ion beam 709 is collimated by an opening 723 in the Faraday cup 721. In addition, the instrument 700 further comprises a sample holder 708. As will be shown further with reference to FIG. 7, the sample holder 708 retains a polymer film 711 and a stencil template 712. The sample holder 708 fixes the polymer film 711 along its surface 108 (FIG. 1) in physical contact with the stencil template 712.

The sample holder 708 further comprising a passage 710 that collimates the ion beam 709 as it travels toward the polymer film 711 through the sample holder 708. Further, as described with reference to FIG. 4, the stencil template 712 further collimates the ion beam 709 passing only those portions of the ion beam 709 that enter into one or more geometrical-shaped openings (not shown) in the stencil template 712. As the ion beam 709 bombards the polymer film 711 through the stencil template 712, wells 203 (FIG. 2) form in the polymer film 711, and after a period of time, pores 204 (FIG. 2) form in the polymer film 711.

The gas pump 706 comprises a valve 714 and a gas reservoir 722. Prior to operation, i.e., prior to bombardment of the polymer film 711 with the ion beam 709, the valve 714 is actuated in a direction indicated by reference arrow 717. As the valve 714 is actuated in the direction indicated by reference arrow 717, a volume (not shown) of gas enters from a gas tank (not shown) through an opening 715 which is pumped with a pump (not shown) out through the opening 716. As the valve 714 is actuated in a direction opposite to the reference arrow 717, gas within a chamber 713 is forced into the gas reservoir 722. In this regard, the gas reservoir 722 fills with gas, e.g., helium gas. Notably, the gas reservoir 722 terminates with an opening 724, which is covered by the polymer film 711. Thus, when the pore 204 forms in the polymer film 711, passage is allowed of the gas from the gas reservoir 722, through the opening 724, through the pore formed in the polymer film 711 and into the vacuum space 707 within the housing 705.

As described herein with reference to FIGS. 1-3, the RGA 304 monitors the partial pressure and mass of the contents within the space 707 within the housing 705. The computing device 301, based upon the partial pressures and the mass values obtained during the monitoring process, deactivates the particle source 102 if the amount of helium within the housing 705 indicates a desired pore size. Furthermore, the Faraday cup 721 is electrically connected via a wire 780 to the counter 302, and the counter 302 determines, based upon current (not shown) flowing from the Faraday cup 721, the fluence of the ion beam 709 bombarding the polymer film 711.

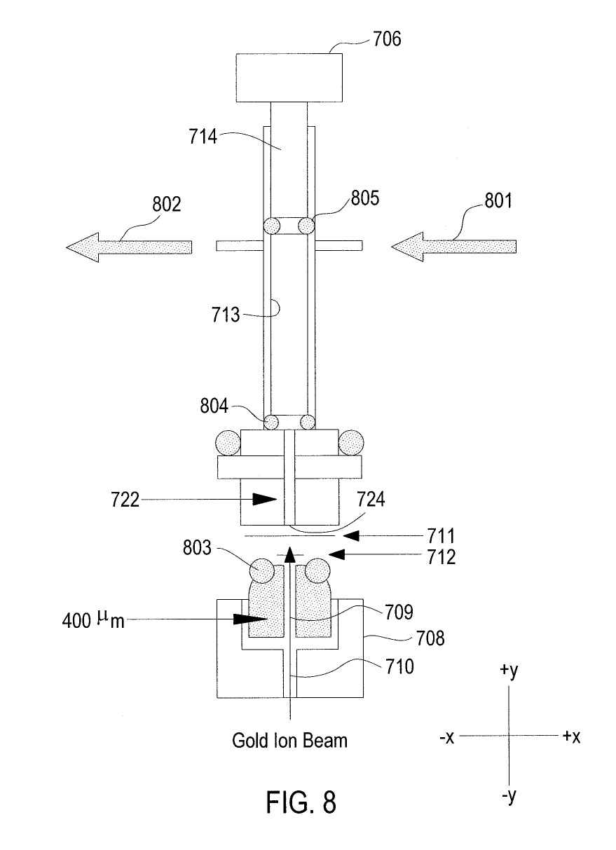

FIG. 8 depicts an exploded cross-sectional view of Detail A of FIG. 7. In this regard, when the valve 714 is actuated in the +y direction, gas flows in a direction as indicated by arrows 801 and 802. Thus, gas fills the chamber 713.

Prior to bombardment, the valve 714 is closed by actuating the valve 714 in the −y direction. Such actuation confines the gas in the gas reservoir 722 with gas from the chamber 713. The gas is then ready to escape from the gas reservoir 722 through the opening 724 to the vacuum space 707 (FIG. 7), when a pore 204 (FIG. 2) is formed in the polymer film 711.

Note that there is a plurality of O-rings 803-805 that are positioned to ensure that the space 707 remains a vacuum. In this regard, the gas flows from the chamber 713, to the gas reservoir 722, and is ready to escape through the polymer film 711 without any external leakage or leakage into the vacuum space 707.

The ion beam 709 enters the channel 710 in the sample holder 708, which collimates the beam 709 and directs it to the stencil template 712. The ion beam 709 bombards the polymer film 711 through the stencil template 712 first forming wells (not shown) then pores (not shown) on the opposing side of the polymer film 711 from which gas in the gas reservoir 722.

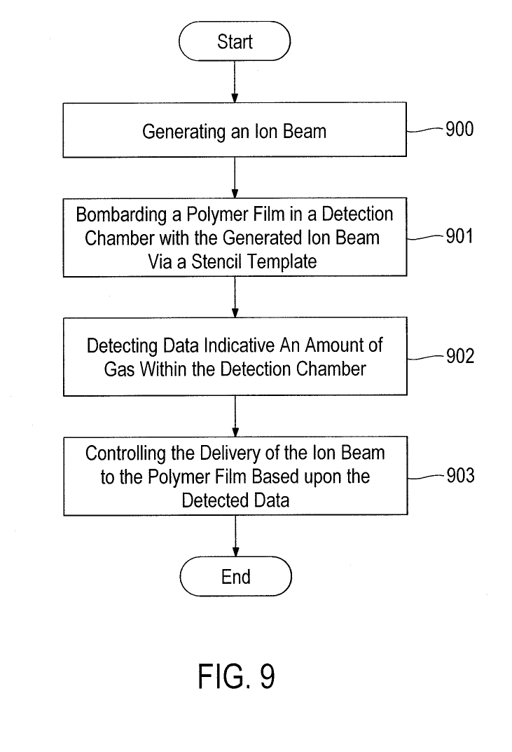

FIG. 9 is a flowchart depicting exemplary architecture and functionality of the system 100 described with reference to FIG. 1. The system 100 generates an ion beam 106 (FIG. 1), as indicated in step 900. The generated ion beam 106 may originate from a particle source 102 (FIG. 1), which can include an ion source 321 (FIG. 3) and one or more deflection plates 312.

The system 100 bombards the polymer film 105 (FIG. 1) through a stencil template 109 (FIG. 1), as indicated by step 901. The polymer film 105 may be bombarded with the ion beam 106 exhibiting any quantity of fluence, as described hereinabove. Notably, the fluence influences the size of the pores 204 (FIG. 2) generated and the duration of time it takes to generate the pores 204.

The system 100 further detects data indicative of an amount of gas within the detection chamber 101 (FIG. 1), as indicated in step 902. As noted herein, there may be an initial trace of helium gas either from natural diffusion through the polymer film 105 or through a trace opening 406 F(G.4). However, when a pore 204 is generated, the amount of gas detected within the detection chamber logarithmically increases.

The system 100 further controls delivery of the ion beam 106 to the polymer film 105 based upon the data detected, as indicated in step 903. In this regard, the system 100 may monitor the fluence over a period of time and deactivate the ion beam 106 based upon the monitored fluence. Alternatively, the system 100 may monitor the quantity of gas within the detection chamber 101 and deactivate the ion beam 106 when the system 100 detects an increase in the gas detected or after a particular duration after the increase in gas is detected.

What is claimed is:

1. A system, comprising:
a particle source for generating an ion beam, the ion beam directed at a polymer film;
a detection chamber for housing the polymer film; and
a controller for controlling the particle source based upon an amount of the gas detected within the detection chamber.

2. The system of claim 1, wherein the polymer film is coupled to a stencil template and the ion beam bombards the polymer film through the stencil template.

3. The system of claim 1, further comprising a gas reservoir, the gas reservoir having an opening.

4. The system of claim 3, wherein the polymer film is coupled to and covers the opening in the gas reservoir.

5. The system of claim 4, wherein the gas reservoir houses an inert gas.

6. The system of claim 5, wherein the ion beam forms a pore in the polymer film.

7. The system of claim 6, wherein the inert gas flows from the gas reservoir to the detection chamber through the formed pore.

8. The system of claim 6, further comprising a residual gas analyzer (RGA) for determining the quantity of the inert gas within the detection chamber.

9. The system of claim 8, wherein the controller is communicatively coupled to the RGA and the controller is further configured to monitor a partial pressure of the inert gas within the detection chamber via the RGA.

10. The system of claim 9, wherein the controller is further configured to deactivate the ion beam when the partial pressure indicates an increase in inert gas within the vacuum chamber.

11. The system of claim 9, further comprising a counter for measuring a real-time fluence of the ion beam.

12. The system of claim 11, wherein the controller is further configured to deactivate the ion beam after a pre-determined duration based upon the measured real-time fluence.

13. A method, comprising:
generating an ion beam;
bombarding a polymer film in a vacuum chamber with the generated ion beam;
detecting data indicative of gas within the detection chamber; and
controlling delivery of the ion beam to the polymer film based upon the detected data.

14. The method of claim 13, wherein the polymer film is coupled to a stencil template and the bombarding step further comprises bombarding the polymer film through the stencil template forming a pore in the polymer film.

15. The method of claim 13, wherein the detecting step further comprises monitoring the partial pressure of the gas over time.

16. The method of claim 15, further comprising the step of activating an ion beam blocker when the partial pressure indicates an increase in gas within the detection chamber.

17. The method of claim 13, wherein the detection step further comprises measuring the real-time fluence of the ion beam.

18. The method of claim 17, wherein the controlling step further comprises activating an ion beam blocker after a pre-determined duration based upon the measured real-time fluence.

19. A system, comprising:
a particle source for generating and transmitting an ion beam;
a vacuum chamber housing a Faraday cup and a polymer film, the polymer film in physical contact with a stencil template, the Faraday cup receiving the ion beam, collimating the ion beam, and transmitting the ion beam, the ion beam directed at the stencil template;
a gas chamber having an opening, the opening covered with the polymer film, the gas chamber further filled with an inert gas;
a residual gas analyzer (RGA) in fluid communication with the detection chamber for detecting the insert gas as the inert gas flows from the gas chamber to the detection chamber through the polymer film; and
a controller for deactivating the particle source when the RGA detects an increase of inert gas within the detection chamber.

20. A method, comprising:
generating a scanned ion beam; and
creating at least one pore in a membrane using the scanned ion beam, the membrane consisting of Teflon covered by a stencil template.

21. The method of claim 20, wherein the creating step further comprises creating at least one nano pore in the membrane using the scanned ion beam.

22. The method of claim 20, wherein the creating step further comprises creating at least one micro pore in the membrane using the scanned ion beam.
